(19) United States
(12) Patent Application Publication
(10) Pub. No.: US 2008/0123727 A1
(43) Pub. Date: May 29, 2008

(54) Apparatus and Method of Equalisation

(75) Inventors: Robert Jan Piechocki, Bristol (GB); Josep Vicent Solder Garrido, Bristol (GB)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Minato-ku, Tokyo (JP)

(21) Appl. No.: 11/813,451

(22) PCT Filed: Apr. 20, 2006
(86) PCT No.: PCT/IL06/00494

§ 371 Date: Jan. 25, 2008

(30) Foreign Application Priority Data
Apr. 12, 2005 (GB) 0507375.4

(51) Int. Cl. H03K 5/159

(52) U.S. Cl. 375/229

(57) ABSTRACT

To reduce the number of components needed when compared with an exact-calculation analog equalizer, an analog equalizer includes an iterative mechanism arranged in operation to generate an estimate of marginal posterior expectations for received bit values.

The invention relates to an apparatus and method of equalisation, and in particular to an apparatus and method of equalisation for MIMO decoding and reading of recordable media with reduced component complexity.

In modern high-speed wireless communications networks, multipath signal propagation is an increasingly significant problem. In traditional wireless communication, a transmit antenna emits an electromagnetic (EM) signal to a receive antenna over an intervening space. However, any obstructions to the signal within that space scatter the EM signal, resulting in copies of the signal reaching the receive antenna at different times and at different intensities via different paths; an effect known as channel spread. In a digital signal, channel spread results in an overlap between successive received bits, and this reduces the confidence in any given bit value received.

To increase bit transmission rates requires shorter bit representations. Consequently, the overlap caused by the same channel spread correspondingly increases, making disambiguation of the received bit stream more difficult. Therefore in high-speed wireless networks, there is a need to mitigate the effect of channel spread.

One approach is multiple input, multiple output (MIMO) communication, wherein multiple transmitter and receiver aerials are used. MIMO systems improve communications robustness by providing multiple, path-independent copies of the transmitted data. This is typically achieved by use of space-time coding techniques, for example Alamouti orthogonal space-time block coding (see S. M. Alamouti, A Simple Transmit Diversity Technique for Wireless Communications, IEEE Journal on Select Areas in Communications, vol. 16, no. 8, October 1998). The result is a set of received signals in which path induced interference differs for each copy of the data, simplifying disambiguation of the common and disparate signal components.

However, MIMO decoding is not a trivial task. Typical detectors use digital signal processing (DSP) methods to decode the MIMO signal; this may involve multiple sampling of each candidate bit signal for each MIMO receiver, and calculating and aggregating bit value probabilities for each sample. These steps incur large computational costs relative to the actual bit rate. The computational costs in turn carry a corresponding power cost that is significant in portable MIMO devices, and can cause a processor bottleneck that limits throughput in high data rate applications. This problem also occurs in other applications where a receive signal is equalised to estimate the source signal, such as surface reading in magnetic storage media.

Recently, an alternative method of MIMO detection has been proposed using analog circuitry rather than digital signal processing (see Piechocki, R. J., Garrido, J., McNamara, D., and McGreen, J., ‘Analogue MIMO detector. The Concept and Initial Results’, IEEE First International Symposium on Wireless Communications Systems, Mauritius, 20-22^{nd} Sep. 2004).

Advantageously, analog circuitry does not require sampling of the incoming signal, and can operate directly on the ‘soft’ (probabilistic) values observed by the receivers. Moreover, the circuitry can be constructed to operate in parallel on the multiple receiver channels.

In consequence, equivalent detector processing can be performed several orders of magnitude more quickly than by the DSP equivalent, whilst simultaneously requiring less power.

However, the analog solution to MIMO detection proposed in Piechocki et. al. above has the drawback that the number of transistors used increases exponentially in proportion to the number of receiver channels. Consequently it is desirable to find a lower complexity solution to analog equalisation for applications such as MIMO detection and mass storage readers.

Accordingly, aspects of the present invention seek to mitigate, alleviate or eliminate the above-mentioned problem.

In one aspect of the present invention, an analog equaliser comprises at least a first analog processing block arranged in operation to generate successively improved estimates of marginal posterior expectations (MPEs) for received bit values.

In one configuration of the above aspect, successive estimates of the MPEs are obtained using a coordinate descent minimisation means.

In another configuration of the above aspect, the analog equaliser updates the MPEs by a temperature factor.

In another configuration of the above aspect, in use a single analog processing block feeds its own outputs back to form its own inputs in successive iterative cycles.

In another configuration of the above aspect, the analog equaliser comprises a plurality of K sets of K−1 R_{k′}.tanh calculation circuits, k=1, . . . , K, where K is the number of MPE estimates, means to sum each of the K sets of K−1 R_{k′}.tanh calculation outputs, means to subtract each said sum from a respective filtered signal zₖ, k=1, . . . , K, and means to scale an output signal for each MPE estimate in inverse proportion to a mean field annealing factor T.

In another aspect of the present invention, an ASIC comprises an analog equaliser as described herein.

In an aspect of the present invention, a multiple input, multiple output detector comprises an analog equaliser as described herein.

In an aspect of the present invention, a wireless communications device comprises an analog equaliser as described herein.

In an aspect of the present invention, a bulk storage device comprises an analog equaliser as described herein.

In another aspect of the present invention, a method of equalisation comprises the step of passing a plurality of log-likelihood marginal posterior expectations to an analog processing block (APB), the APB in turn generating a revised estimate of the log-likelihood marginal posterior expectations using coordinate descent optimisation.

Although the present invention has been described hereinabove with reference to a number of separate aspects, in accordance with the present invention any aspect of the present invention described previously can be used in conjunction with any other aspect of the present invention.

Embodiments of the present invention will now be described by way of example with reference to the accompanying drawings, in which:

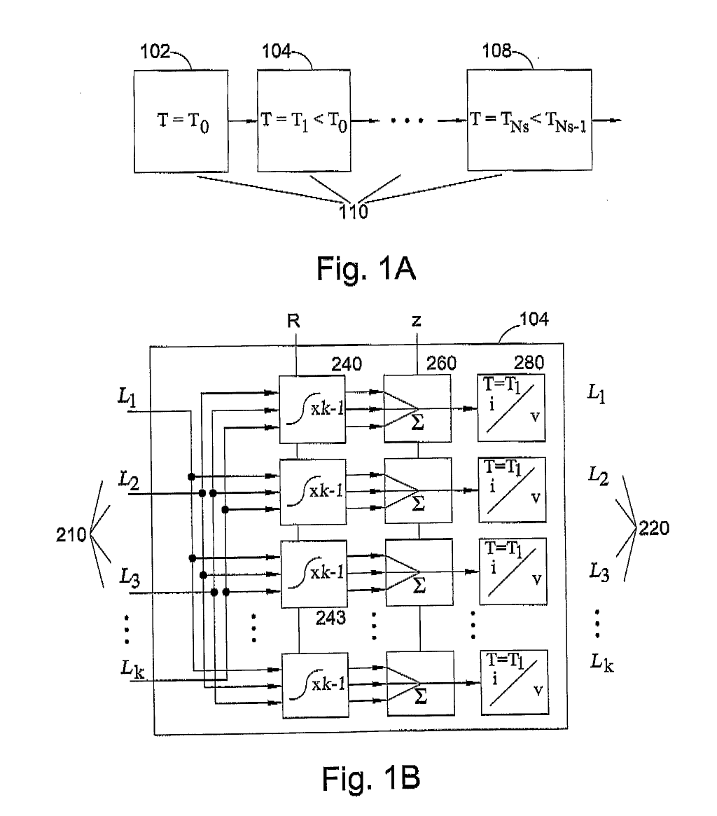

FIG. 1A is a schematic diagram of a single analog processing block in accordance with an embodiment of the present invention.

FIG. 1B is a schematic diagram of an analog MIMO detector comprising a plurality of analog processing blocks, in accordance with an embodiment of the present invention.

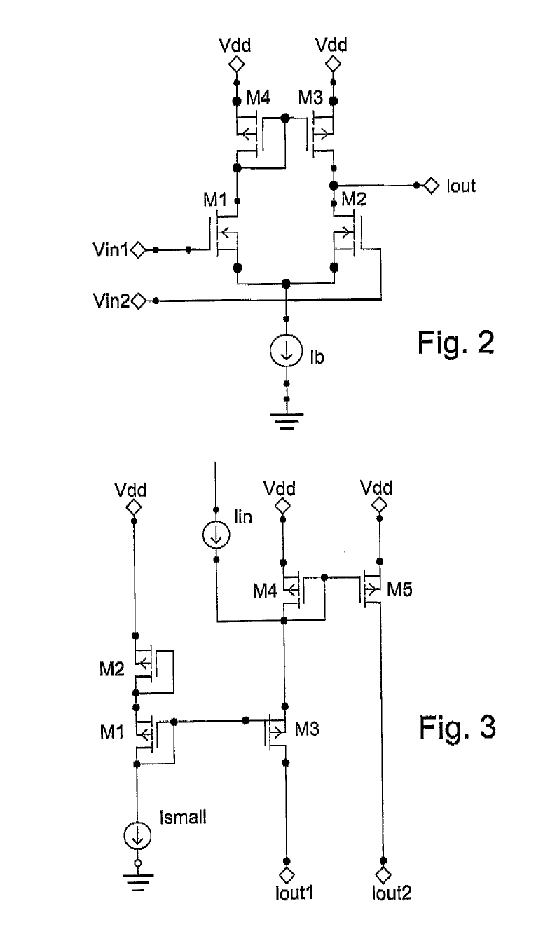

FIG. 2 is a MOS transconductance amplifier, for use in an embodiment of the present invention.

FIG. 3 is an absolute value circuit, for use in an embodiment of the present invention.

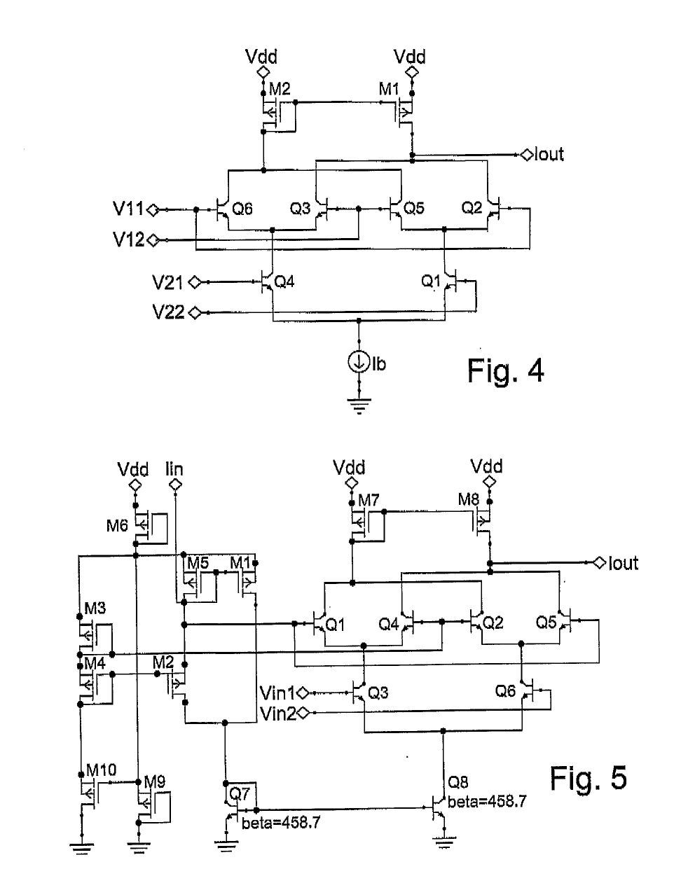

FIG. 4 is a Gilbert multiplier, for use in an embodiment of the present invention.

FIG. 5 is a tanh calculator circuit in accordance with an embodiment of the present invention.

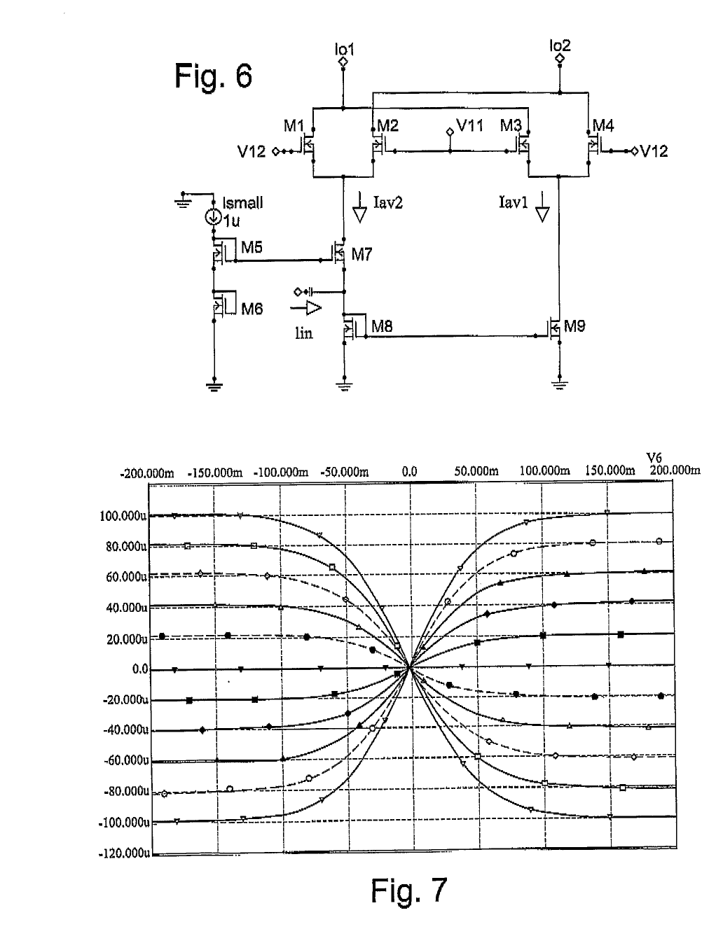

FIG. 6 is a tanh calculator circuit in accordance with an embodiment of the present invention,

FIG. 7 is a graph showing the response of a tanh calculator block in accordance with an embodiment of the present invention, with input voltage on the x-axis and output current on the y-axis.

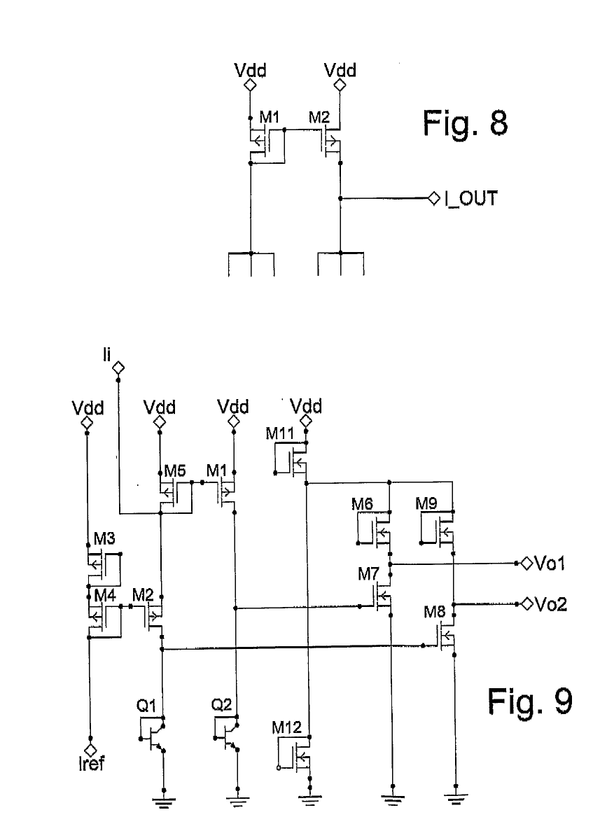

FIG. 8 is a subtraction circuit, for use in an embodiment of the present invention.

FIG. 9 is a transresistance circuit, for use in an embodiment of the present invention.

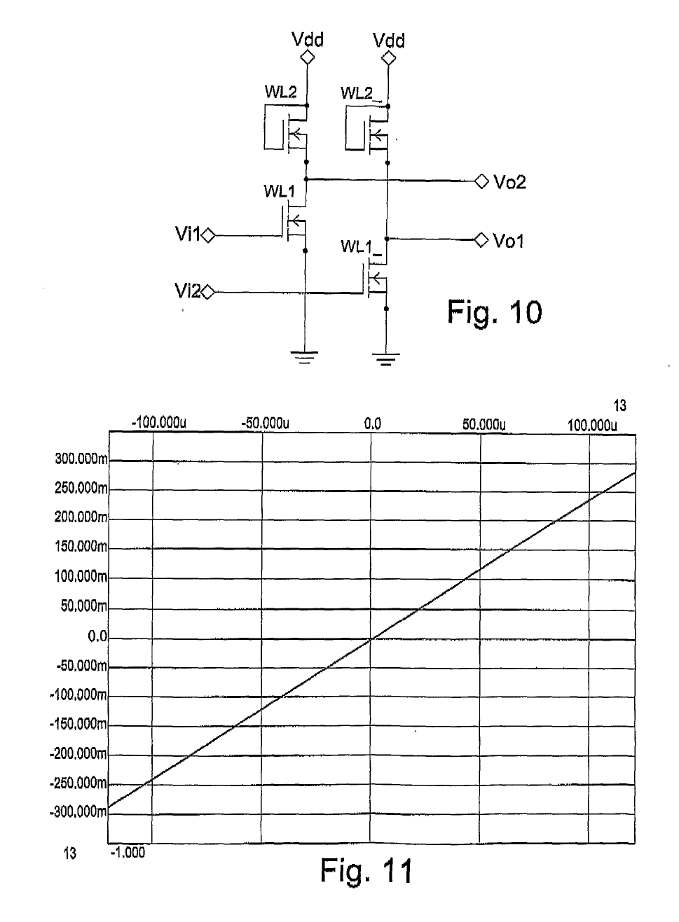

FIG. 10 is a voltage shifter, for use in an embodiment of the present invention.

FIG. 11 is a graph showing the DC response of a transresistance circuit, with input current on the x-axis and output voltage on the y-axis.

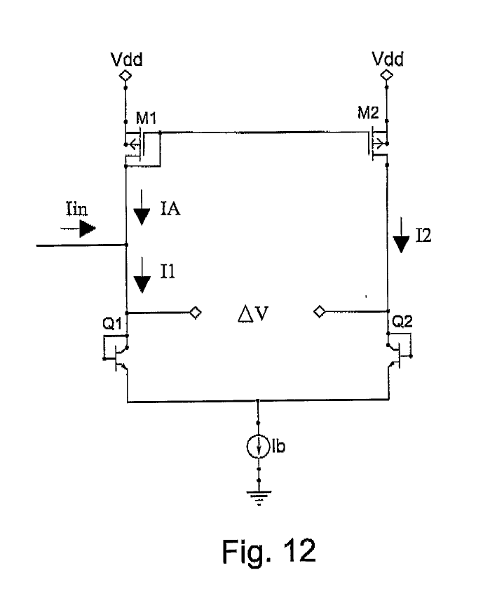

FIG. 12 is a current to voltage converter, for use in an embodiment of the present invention.

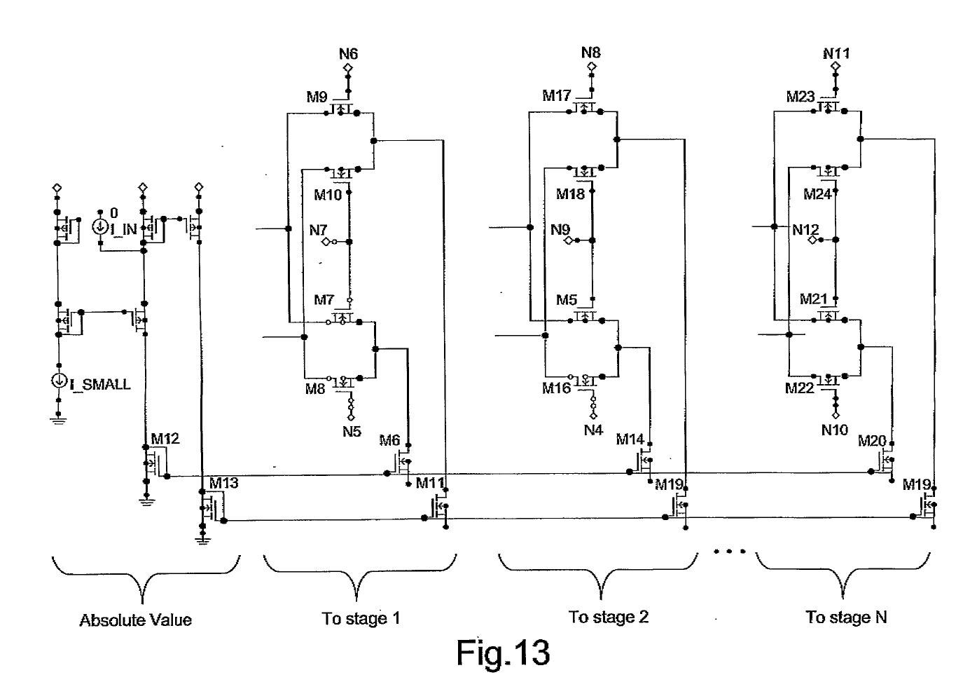

FIG. 13 illustrates sharing an absolute value circuit between corresponding tanh calculator circuits in accordance with an embodiment of the invention.

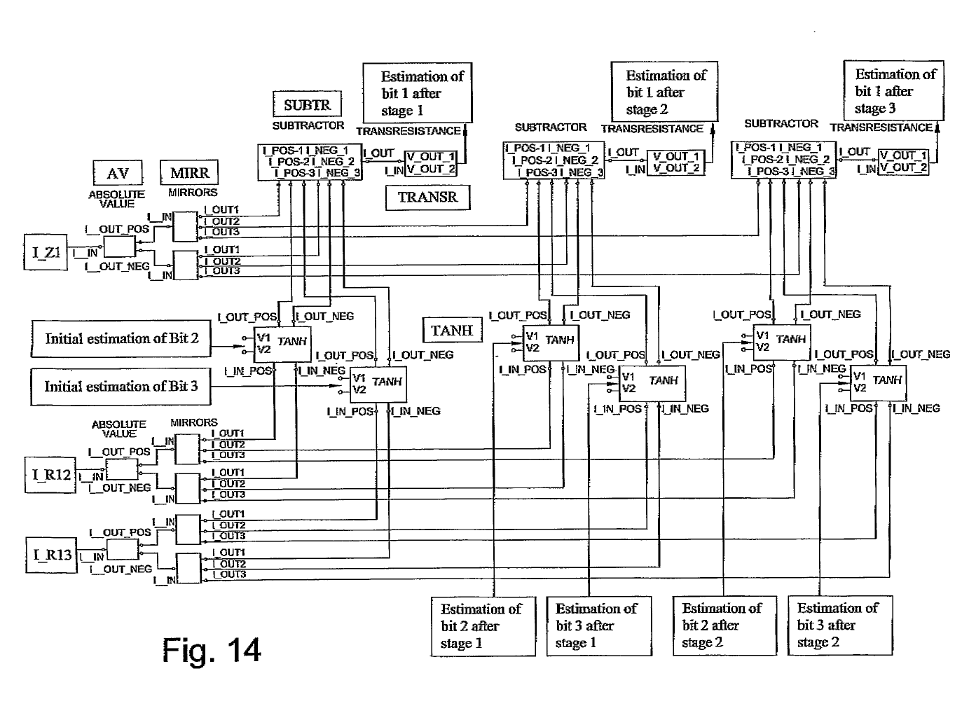

FIG. 14 illustrates the arrangement of circuits to estimate one of three received bits in an analog MIMO detector in accordance with an embodiment of the present invention.

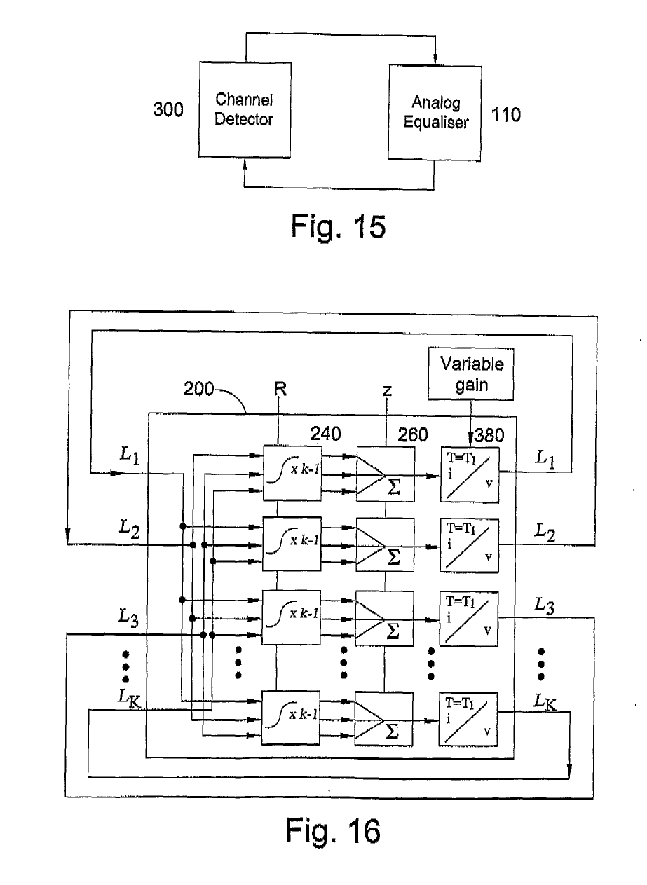

FIG. 15 is a schematic diagram of an analog equaliser arranged in conjunction with a channel detector, in accordance with an embodiment of the present invention

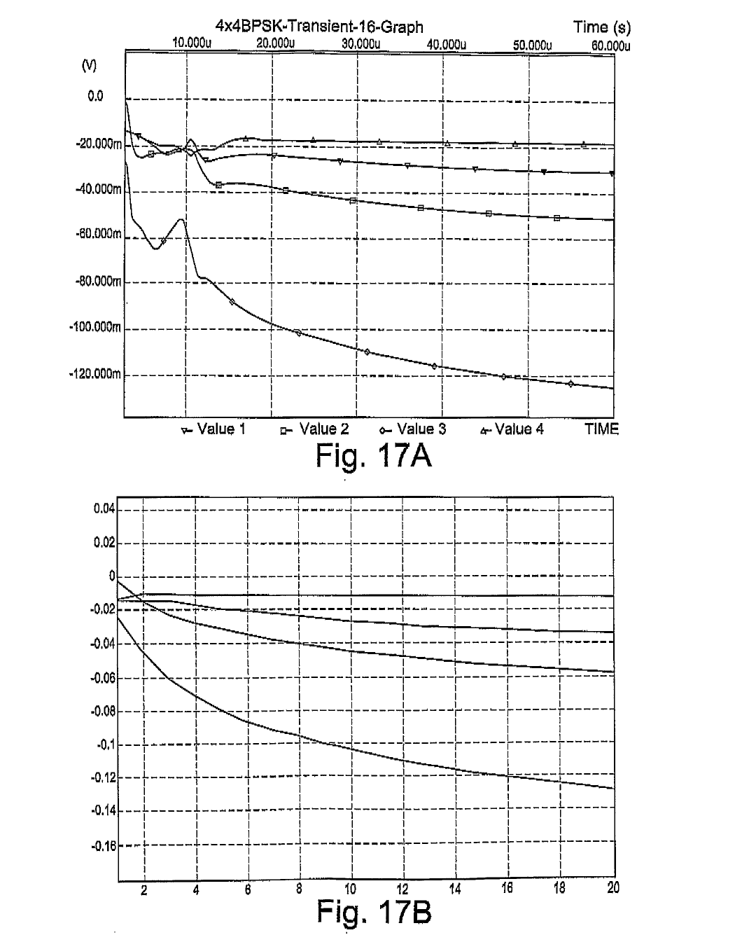

FIG. 16 is a schematic diagram of a single recurrent analog processing block in accordance with an embodiment of the present invention.

FIGS. 17A and 17B are graphs illustrating marginal posterior expectation estimates for a recurrent analog processing block and a plurality of analog processing blocks respectively, where time is on the x-axis, and estimate values are expressed as voltages on the y-axis.

An analog MIMO detector is disclosed. In the following description, a number of specific details are presented in order to provide a thorough understanding of embodiments of the present invention. It will be apparent to a person skilled in the art, however, that these specific details need not be employed to practice the present invention.

### Theoretical Background

A model of MIMO signal reception well known in the art is

y=Hx+n (1)

where x is a transmitted data vector from N_{T} transmit antennas, y is the received vector, H is the matrix of channels between each transmit and receive antennas and n is a vector of independent Gaussian noise distributions.

Applying a channel-matched filter H^{H}, the signal model becomes

z=H^{H}y=H^{H}Hx+H^{H}n=Rx+v (2)

where R=H^{H}H and v=H^{H}n˜N(0,σₙ²R).

Thus the likelihood of a value in filtered signal z is

$$f ( z \vert x , R , {σ}_{n}^{2} ) = \frac{1}{\sqrt{{πσ}_{n}^{2} \vert R \vert}} exp [ - \frac{1}{{σ}_{n}^{2}} {( z - Rx )}^{H} {R}^{- 1} ( z - Rx ) ] . \qquad ( 3 )$$

Assuming uniform priors, then

f(x|z,R,σₙ²)∝f(z|x,R,σₙ²). (4)

The marginal posterior expectations

mₖ=E{xₖ|zₖ} (5)

are then computed, and the sign taken, to derive a binary value.

It can be further shown that

$${m}_{k} = E \{ tanh ( \frac{1}{{σ}_{n}^{2}} ( {z}_{k} - {\sum }_{{k}^{′} \neq k} {R}_{k , {k}^{′}} {x}_{{k}^{′}} ) ) \} . \qquad ( 6 )$$

(e.g. see Fabricius, T and Winther, O, ‘Correcting the bias of subtractive interference cancellation in CDMA—Advanced mean field theory’, submitted to IEEE trans. Information Theory, and soil published at http://isp.immn.dtu.dk/staff/winther/fabricius.ieeeinformationtheory.pdf, as at 15/03/2005).

However, it is difficult to evaluate the expectations in equation (6), as the tanh function is asymptotic in character.

### Description of New Approach

Notably, a mean field approach to the problem may be taken by approximating the expectations [symbol] tanh( . . . ) [symbol] as tanh( [symbol] . . . [symbol] ). Applying this approximation to equation (6) gives

$$\begin{matrix}{m}_{k} = E \{ tanh ( \frac{1}{{σ}_{n}^{2}} ( {z}_{k} - {\sum }_{{k}^{′} = k} {R}_{k , {k}^{′}} {x}_{{k}^{′}} ) ) \} \\ ≅ tanh ( E \{ \frac{1}{{σ}_{n}^{2}} ( {z}_{k} - {\sum }_{{k}^{′} \neq k} {R}_{k , {k}^{′}} {x}_{{k}^{′}} ) \} ) \\ {m}_{k} = tanh ( \frac{1}{{σ}_{n}^{2}} ( {z}_{k} - {\sum }_{{k}^{′} \neq k} {R}_{k , {k}^{′}} {m}_{{k}^{′}} ) ) .\end{matrix}$$

Thus, applying a mean field approach to the model of marginal posterior expectations (hereinafter MPEs) generates a recursive solution for mₖ. Iterating equation (7) corresponds to a coordinate descent minimisation of the cost function of the free energy, thus guaranteeing that at least a local minimum value is found.

To improve the chance of finding a global minimum in the descent minimisation problem, mean field annealing may be applied. In mean field annealing, a variable temperature T is used in place of the noise σₙ² in equation (7). Thus an annealing schedule may be used wherein following an initial and comparatively high value of T, subsequent iterations of equation (7) use decreasing values back toward or even below the original noise floor (See Fabricius, T and Winther, O, ibid). Note that such mean field annealing does not result in probabilistic gradient ascent dependent on T, as in simulated annealing.

The inventors of the present invention have appreciated that a suitable structure may be constructed in analog circuitry to iterate toward a solution for mₖ in the fashion described above, so providing the building blocks for a lower complexity analog equaliser for MIMO detection based upon approximating mₖ rather than providing an exact calculation.

Applying mean field annealing to equation (7) gives a general form for mₖ as;

$${m}_{k} = a tanh ( \frac{a}{T} ( {z}_{k} - {\sum }_{{k}^{′} = k} {\hat{R}}_{{k}^{′}} {m}_{{k}^{′}} ) ) , \qquad ( 8 )$$

where temperature T lowers with each re-estimation of mₖ, and a is a constant.

In principle, the tanh function is readily implementable using analog circuits; for example, the well-known Gilbert multiplier circuit inherently computes tanh for its inputs, normally relying on the linearising approximation tanh(x)≈x for small values to perform its multiplier operation.

In analog calculations, means such as mₖ are generally computed as differential currents. However, in a recursive problem such as that of equation (8), distributing the new values of one mₖ iteration at the input to a further iteration would require k−2 copies of each current using current mirrors resulting in a large number of components.

To reduce this problem, the posterior expectations mₖ are re-expressed as log-likelihood ratios using an inverse hyperbolic tangent:

$${L}_{k} = 2 {tanh}^{- 1} ( \frac{{m}_{k}}{a} ) \qquad ( 9 )$$

Substituting equation (9) into (8) gives

$${L}_{k} = \frac{2 a}{T} ( {z}_{k} - a {\sum }_{{k}^{′} = k} {\hat{R}}_{{k}^{′}} tanh ( \frac{{L}_{{k}^{′}}}{2} ) ) \qquad ( 10 )$$

The output of (10) may be expressed using a differential voltage, rather than a differential current. This allows the MPE estimates of one iterative stage to be directly connected to the inputs of another with no need for copying.

### Overview of the Analog Process

Referring now to FIGS. 1A and 1B, in an embodiment of the present invention, the analog MIMO detector employs a plurality of analog processing blocks (APBs) (102, 104, 108, collectively referenced as 110), each implementing an iteration stage of equation 10.

APB 104 is taken as an example in FIG. 1B and discussed in functional terms below. For clarity, implementation issues are deferred to specific sections further on.

A plurality of K log likelihood ratio MPEs Lₖ, k=1, . . . K, are input 210 to the APB 104 as voltages. These inputs are distributed to a plurality of tanh calculators (collectively referenced 240). For each k^{th} bit whose MPE is being estimated, there are K−1 tanh circuits. All but the k^{th} input is passed to the respective K−1 tanh calculators in each of these K sets.

Thus, for example, the plurality of K−1 tanh calculators 243 associated with L₃ will receive all Lₖ inputs other than L₃ itself. In addition, each set of K−1 tanh calculators receives the relevant elements of the channel estimation matrix R. The output of each individual tanh calculator is

$${\hat{R}}_{{k}^{′}} tanh ( \frac{{L}_{{k}^{′}}}{2} )$$

for one value of k for its corresponding Lₖ.

The outputs of the K−1 tanh functions for each Lₖ are then summed, and subtracted from z 260. The output is then a partial calculation

$${z}_{k} - a {\sum }_{{k}^{′} = k} {\hat{R}}_{{k}^{′}} tanh ( \frac{{L}_{{k}^{′}}}{2} )$$

of equation (10) for each Lₖ.

The value of T relevant to the current iteration stage is then used in scaling 280 an output voltage representing the updated estimate for each Lₖ 220, which may then be used as input for the next iteration, or taken as the final estimate.

The implementation of the functional elements disclosed above will now be discussed in detail.

### Tanh Function (1)—Nonlinearity and Multiplication

Referring now to FIG. 2, in an embodiment of the present invention the analog circuit to perform the hyperbolic tangent and multiplication comprises a simple differential pair with a mirror to subtract the output currents, i.e. a basic transconductance amplifier.

The output current of this circuit is given by

$${I}_{out} = {I}_{b} \cdot tanh ( \frac{Δ {V}_{i n}}{2 {V}_{T}} ) .$$

Therefore, an output current

$${\hat{R}}_{{k}^{′}} tanh ( \frac{{L}_{{k}^{′}}}{2} )$$

can be obtained by representing log likelihood ratios Lₖ as differential voltages (normalised to the thermal voltage), and defining the bias current I_{b} as proportional to the input value R_{k′} (i.e. I_{b}=I_{ref}Rₖ) from the channel estimator.

Advantageously, the plurality of output currents may be summed together without the need for any additional transistors according to Kirchoff's current law, to provide partial calculation

$$a {\sum }_{{k}^{′} = k} {\hat{R}}_{{k}^{′}} tanh ( \frac{{L}_{{k}^{′}}}{2} )$$

of equation (10).

However, whilst the bias current to the above circuit must be positive, the input values of R_{k′} may be positive or negative. This discrepancy must be resolved.

### Tanh Function (2)—Absolute Values and Sign Management

Referring now to FIG. 3, in a first embodiment of the present invention, to overcome the problem of bias current sign a translinear circuit is provided to obtain the absolute value of R_{k′}.

The circuit of FIG. 3 comprises two translinear loops. The first loop uses transistors M2-M1-M3-M4, so that I₂I₁=I₃I₄. Substituting the values of the currents gives: IₛₘₐₗₗIₛₘₐₗₗ=Iₒᵤₜ₁(Iₒᵤₜ₁−Iᵢₙ). The second translinear loop is formed by M4 and M5, forming a simple current mirror so that Iₒᵤₜ₂=I₄=Iₒᵤₜ₁−Iᵢₙ.

These equations can be solved to obtain the output currents in terms of the input currents:

$${I}_{out 1} = \frac{1}{2} ( {I}_{i n} + \sqrt{4 {I}_{small}^{2} + {I}_{i n}^{2}} )$$

$${I}_{out 2} = \frac{1}{2} ( - {I}_{i n} + \sqrt{4 {I}_{small}^{2} + {I}_{i n}^{2}} )$$

where Iₛₘₐₗₗ is a small bias current compared to Iᵢₙ. This circuit then behaves like an absolute value circuit that for positive input currents obtains Iₒᵤₜ₁≈|Iᵢₙ|, Iₒᵤₜ₂≈0, and for negative input currents obtains Iₒᵤₜ₁≈0, Iₒᵤₜ₂≈|Iᵢₙ|.

Obtaining the absolute value of R_{k′} allows the transconductance amplifier to operate as desired. However, the correct sign of the input value R_{k′} must still be preserved for subsequent reincorporation.

In an embodiment of the present invention, the sign is obtained from the voltage difference between the gates of M2 and M4 of the tanh block. If Iᵢₙ>0, then the current flows through M3; otherwise, the current flows through M4. Thus depending on the sign of Iᵢₙ, the voltage at the gate of M4 will either be close to V_{dd} or to ground. A differential voltage representing the sign of the input signal is obtained when the voltage at the gate of M4 is compared with a reference, for example the gate of M2.

To apply this sign to obtain the desired expression one may use a Gilbert multiplier, as depicted in FIG. 4.

The output current of the multiplier is

$${I}_{out} = {I}_{small} \cdot tanh ( \frac{Δ {V}_{i n 1}}{2 {V}_{T}} ) tanh ( \frac{Δ {V}_{i n 2}}{2 {V}_{T}} ) .$$

Therefore, the combined circuit uses the absolute value of the current representing the value R_{k′} and a log-likelihood ratio voltage as inputs, and further applies the sign of the bias current, to obtain the final following expression:

$${I}_{out} = {I}_{ref} \vert R \vert \cdot sgn ( R ) \cdot tanh ( \frac{L}{2} ) = {I}_{ref} R \cdot tanh ( \frac{L}{2} ) \qquad ( 11 )$$

Note that using a four quadrant Gilbert multiplier may suggest the use of Rₖ, as an input voltage, without the need for using an absolute value process. However, simulations have shown that the values of matrix R are typically too big for the tanh(x)≈x approximation to hold for multiplications.

The combined tanh function circuit comprising the transconductance and absolute values circuits disclosed above can be seen in FIG. 5.

However, in a preferred embodiment of the present invention, the sign of R_{k′} may be more efficiently managed using the tanh function circuit illustrated in FIG. 6.

Here, transistors M5 to M9 form an absolute value circuit, and by virtue of the use of NMOS rather than PMOS transistors these form a current sink rather than a current source. Consequently, currents Iₐᵥ₁ and Iₐᵥ₂ pass into this sink and so the absolute value circuit can connect directly with the tanh block formed by transistors M1 to M4.

This preferred embodiment operates in a similar manner to the embodiment described previously. A first translinear loop formed by M5 and M6 acts in a clockwise direction, and a second translinear loop formed by M7 and M8 acts in an anticlockwise direction. Consequently the current through M5 and M6 is forced to be a small current Iₛₘₐₗₗ and the currents through M7 and M8 are Iₐᵥ₂ and (Iₐᵥ₂+Iᵢₙ) respectively. This arrangement gives current equation

### Iₛₘₐₗₗ²=Iₐᵥ₂·(Iₐᵥ₂+Iᵢₙ), for which the solution is

$${I}_{av 2} = \frac{1}{2} ( - {I}_{i n} + \sqrt{{I}_{i n}^{2} + 4 {I}_{small}^{2}} ) .$$

Transistors M8 and M9 form a current mirror so that the current through M9 is also (Iav2+Iin). Therefore, Iav1 is expressed by

$${I}_{av 1} = {I}_{i n} + {I}_{av 2} = \frac{1}{2} ( {I}_{i n} + \sqrt{{I}_{i n}^{2} + 4 {I}_{small}^{2}} ) .$$

For Iᵢₙ>>Iₛₘₐₗₗ, this circuit therefore behaves like an absolute value circuit that for positive input currents produces Iₐᵥ₁≈|Iᵢₙ|, Iₐᵥ₂≈0 and for negative input currents produces Iₐᵥ₁≈0, Iₐᵥ₂≈|Iᵢₙ|.

Similarly, the sign also feeds directly into the tanh calculation as a function of whether Iₐᵥ₁ or Iₐᵥ₂ is non-zero, as opposing differential pairs in the tanh block receive the input current depending upon the original sign.

The differential voltage applied to both differential pairs is the same as in the previous embodiment, but with the terminals swapped, i.e, +ΔV is applied to one and −ΔV to the other, inverting the polarity between them. Finally, output currents of the differential pairs are summed appropriately (positive with negative and negative with positive), where positive and negative refer to the terminal of ΔV applied to each branch; for example in the case of FIG. 6, the current that comes from the first pair from the V₁₁ branch is summed with the current coming from the second pair from the V₁₂ branch.

This arrangement preserves the sign information, and so the final current

$${I}_{out} = {I}_{i n} tanh ( \frac{Δ V}{2 {nV}_{T}} )$$

is obtained by subtracting Iₒ₂ from Iₒ₁. The ‘n’ in the preceding expression is a relative scaling factor reflecting the use of MOS transistors instead of BJTs.

Note that as there is a plurality (k−1) of tanh calculations to perform prior to summation for the k^{th} MPE, it may be advantageous to keep Iₒ₂ and Iₒ₁ separate, sum all Iₒ₂s and Iₒ₁s, and then perform the subtraction to obtain an aggregate tanh calculation. This would then only require one current mirror, but the currents involved would be much higher than for individual subtractions and so performance could be affected. These two alternative approaches would therefore be a matter for selection by a person skilled in the art, dependant upon the current levels used in their specific detector hardware.

For the embodiment of either FIG. 5 or FIG. 6, the response of the circuit for different voltage and current inputs is shown in FIG. 7, demonstrating R_{k′}-scaled tanh function outputs.

In an alternative embodiment of the present invention, the whole circuit of FIG. 6 is implemented using PMOS transistors and the absolute value circuit of FIG. 3, but now changing the differential pairs to use PMOS transistors. In this configuration, both parts of the circuit work as current sources and so direct connection between them would similarly be possible.

### Summation

As noted previously, for either of the above embodiments, the Iₒᵤₜ for each of the plurality of R_{k′,k′≠k} tanh calculations are then simple to sum using Kirchoff's law, as prescribed in equation 10.

### Subtraction from zₖ

Referring now to FIG. 8, a subtractor circuit as illustrated that may be used for the first embodiment of the tanh circuit as seen in FIG. 5. This subtractor circuit acts as a current mirror to subtract currents. It takes six currents with duplicate values for zₖ and for R_{k′} (as split by the absolute value circuit), and then sums the positive and negative parts before finally obtaining the difference between the two resulting currents.

In the preferred embodiment of the tanh circuit as seen in FIG. 6, subtraction from zₖ may be more simply achieved by swapping the input voltage terminals to produce

$${I}_{out} = - {I}_{i n} tanh ( \frac{Δ V}{2 {nV}_{T}} ) .$$

### This is then ‘added’ to I_{z} using Kirchoff's law, for example during summation of the k−1 tanh calculations.

In either case, the output current represents the partial calculation

$${z}_{k} - a {\sum }_{{k}^{′} = k} {\hat{R}}_{{k}^{′}} tanh ( \frac{{L}_{{k}^{′}}}{2} )$$

of equation 10.

### Formatting the Result (1)—Current to Voltage Conversion and Annealing

The result of the above processes gives an interim a-posteriori log-likelihood ratio for the received symbol mₖ as seen in equation 10, and expressed as a current:

$$I = {I}_{ref} L = {I}_{ref} [ {z}_{k} - {\sum }_{{k}^{′} = k} {\hat{R}}_{{k}^{′}} tanh ( \frac{{L}_{{k}^{′}}}{2} ) ] ,$$

where I_{ref} is a chosen reference current used in mapping the values of R_{k′} and zₖ within the circuits, i.e. I_{z}=I_{ref}*zₖ and Iᵣ=I_{ref}*Rₖ.

However, recall that the tanh calculation circuit described above takes a differential voltage representation of the log-likelihood ratios as its inputs. Therefore, in order to pass the result of the above process to a subsequent iterative stage of the equaliser, it is necessary to re-express the output current as a differential voltage normalised by the thermal voltage. During this step, the mean field annealing factor 2a/T may also be included.

To this end, a circuit is needed that linearly converts a current to a voltage in the form

$$Δ {V}_{out} = {V}_{T} \cdot \frac{{I}_{i n}}{{I}_{ref}} .$$

Typically, current-to-voltage conversion is by means of diode-connected transistors that have a logarithmic response, i.e.

$$Δ {V}_{out} = {V}_{T} log \frac{{I}_{i n}}{{I}_{ref}} .$$

In an embodiment of the present invention, a circuit similar to the absolute value circuit of FIG. 3 may be used to provide current-to-voltage conversion; as noted previously in relation to this circuit, it only acts as an absolute value circuit when bias current Iₛₘₐₗₗ is small compared to Iᵢₙ. However, when this condition is not met, the circuit acts as a current to voltage converter, albeit with a response that follows an inverse hyperbolic tangent relationship rather than a truly linear one. Renaming Iₛₘₐₗₗ as I_{b}:

$$\begin{matrix}Δ {V}_{out} = {V}_{T} log ( \frac{\frac{1}{2} ( {I}_{i n} + \sqrt{4 {I}_{b}^{2} + {I}_{i n}^{2}} )}{\frac{1}{2} ( - {I}_{i n} + \sqrt{4 {I}_{b}^{2} + {I}_{i n}^{2}} )} ) \\ = {V}_{T} log ( \frac{1 + \frac{{I}_{i n} / {I}_{b}}{\sqrt{4 + {( {I}_{i n} / {I}_{b} )}^{2}}}}{1 - \frac{{I}_{i n} / {I}_{b}}{\sqrt{4 + {( {I}_{i n} / {I}_{b} )}^{2}}}} ) \\ = 2 {V}_{T} {tanh}^{- 1} ( \frac{\frac{{I}_{i n}}{{I}_{b}}}{\sqrt{4 + {( {I}_{i n} / {I}_{b} )}^{2}}} )\end{matrix} \qquad ( 12 )$$

Fortunately, however, like tanh the inverse is approximately linear for small values and tanh⁻¹(x)≈x when x is less than about 2. Therefore providing that Iᵢₙ<2I_{b}, such a circuit can be used.

FIG. 9 illustrates a transresistance circuit, incorporating the above absolute value circuit acting as a current-to-voltage converter, to implement equation 12. Recalling that a current I=I_{ref}·L currently gives the log-likelihood ratio within the APB, one obtains a voltage representation given by

$$Δ {V}_{out} = 2 {V}_{T} {tanh}^{- 1} ( \frac{\frac{{I}_{ref}}{{I}_{b}} L}{\sqrt{4 + {( {I}_{ref} L / {I}_{b} )}^{2}}} ) \approx {V}_{T} \frac{{I}_{ref}}{{I}_{b}} L \qquad ( 13 )$$

As noted above, such a circuit only acts approximately linearly up to some maximum input value Iₘₐₓ=M*I_{b}, where I_{b} is the bias current. In the case of the circuit of FIG. 9, this value M is approximately 2.

Therefore in order to linearly obtain log likelihood voltages up to some value Lₘₐₓ, it is necessary to ensure that Lₘₐₓ≦M or thereabouts. This is achieved by setting

$${I}_{b} = {L}_{max} \frac{{I}_{ref}}{M} .$$

### The transresistance block consequently outputs

$$Δ {V}_{out} \approx {V}_{T} \frac{{I}_{i n}}{{I}_{bias}} = {V}_{T} \cdot \frac{M}{{L}_{max}} \frac{{I}_{i n}}{{I}_{ref}} .$$

Thus for the circuit of FIG. 9, the bias current must be set to

$${I}_{b , max} = \frac{{I}_{ref}}{2} {L}_{max} .$$

### Then, for example, if one sets the maximum Lₘₐₓ to 10, I_{b}=5I_{ref} and the output of the circuit will give the value

$$Δ {V}_{out} \approx {V}_{T} \frac{L}{5} .$$

In an embodiment of the present invention, the annealing factor 2a/T is also incorporated into the current to voltage converter scaling calculation. This may be achieved simply by substituting

$${I}_{b} = {L}_{max} \frac{{I}_{ref}}{M} with {I}_{b} = 2 \frac{a}{T} {L}_{max} \frac{{I}_{ref}}{M} .$$

### Formatting the Result (2)—Voltage Scaling

Having obtained a differential voltage output using the circuit described above, it will therefore be necessary to amplify it by a restorative factor. In the above-enumerated example this would be a factor of 5 to obtain the desired value for the log-likelihood ratio.

Referring now also to FIG. 10, in an embodiment of the present invention, the amplification can be performed with a MOS level shifter, as seen in FIG. 10 and as incorporated into the transresistance circuit of FIG. 9.

Providing that the transistors are working in strong inversion, the circuit has a transfer function of the type

$$Δ {V}_{out} = \sqrt{\frac{{W}_{1} / {L}_{1}}{{W}_{2} / {L}_{2}}} Δ {V}_{i n}$$

where W is the width of the transistors, L is the length, and 1 and 2 refer to the bottom and top pair of transistors in FIG. 10 respectively. Because transistors are typically fabricated with similar lengths, in order to amplify the voltage by a factor of 5 therefore requires the bottom pair of transistors to be 25 times wider than the top pair.

In an embodiment of the present invention, the annealing factor 2a/T can be included during amplification. Note that because the value of T varies as a position of each analog processing block in within the equaliser's iterative chain, further including the annealing factor 2a/T means that the amplification, and therefore the relative width of the bottom and top transistors in the circuit of FIG. 9, will need to be selected to reflect the value of T in each analog processing block.

Thus for example, given an equaliser in which a=0.5, Lₘₐₓ=10 and K−1, and wherein T varied from 10 to 0.1 over the annealing schedule, then the amplification factor in the first analog processing block would be 2*0.5*10/(1*10)=1, whilst the amplification factor in the last would be 2*0.5*10/(1*0.1)=100.

Referring now to FIG. 11, the substantially linear current-to-voltage relationship of the transresistance circuit incorporating the MOS level shifter is shown in the graph, with input current on the x-axis and output voltage on the y-axis.

The person skilled in the art will appreciate that alternative arrangements are possible to implement the transresistance circuit, and these are envisaged within the scope of the present invention. Similarly, the person skilled in the art will appreciate that other current to voltage converters are possible, and these are likewise envisaged within the scope of the present invention. For example, referring now to FIG. 12, in an alternative embodiment of the present invention, the circuit of FIG. 12 may be employed as a current to voltage converter, In this circuit, M1 and M2 form a current mirror so that I₂=I_{A}. Moreover, it can be seen that I₁=I_{A}+Iᵢₙ. Currents I₁ and I₂ are then forced to sum I_{b}; I₁+I₂=I_{b}. Solving this system of equations for I₁ and I₂ gives:

$${I}_{1} = \frac{1}{2} ( {I}_{b} + {I}_{i n} ) and {I}_{2} = \frac{1}{2} ( {I}_{b} - {I}_{i n} ) .$$

By virtue of the aforementioned logarithmic relationship, the output voltage is

$$\begin{matrix}Δ V = {V}_{T} \cdot log ( \frac{{I}_{1}}{{I}_{2}} ) \\ = {V}_{T} \cdot log ( \frac{{I}_{b} + {I}_{i n}}{{I}_{b} - {I}_{i n}} ) \\ = {V}_{T} \cdot log ( \frac{1 + \frac{{I}_{i n}}{{I}_{b}}}{1 - \frac{{I}_{i n}}{{I}_{b}}} ) \\ = 2 {V}_{T} \cdot {tanh}^{- 1} ( \frac{{I}_{i n}}{{I}_{b}} ) .\end{matrix}$$

Thus this circuit also provides acceptable linearity, but for a smaller range (M=0.5) than the previously disclosed adapted absolute value circuit of FIG. 3 (M≈2).

### Considerations for Multiple Analog Processing Blocks

In one analog processing block, the output of matrix R=Rᵢⱼ, i,j=1, . . . , K from the channel estimator provides the required inputs to the mₖ bit estimations in the form of the k^{th} row of the matrix (excepting Rₖₖ as it is not needed).

However, for a MIMO detector comprising an iterative chain of discrete analog processing blocks, each block requires a copy of R.

Recall, however, that generating copies using current mirrors assumes that the current is positive, whilst values of R may be positive or negative. In an embodiment of the present invention, values of R are passed through an absolute value circuit to obtain two value streams (one positive current and one null current, which is which being dependent on the sign of the input value as detailed previously). The positive currents may then be copied.

Advantageously therefore, one would only need one absolute value circuit for each corresponding tanh calculator in the chain of analog processing blocks. Such an arrangement is depicted in FIG. 13.

In FIG. 13, one sees that the absolute value circuit of FIG. 3, using PMOS transistors, can be directly input to a tanh circuit as the current mirrors change the direction of the currents, allowing direct connection. Consequently the tanh calculator depicted is that of FIG. 6 minus the absolute value circuit shown therein, i.e. only transistors M1 to M4, directly connected to the copies of the absolute value currents.

In summary, FIG. 14 provides a schematic diagram illustrating how an analogue processor block (APB) according to an embodiment of the present invention would be arranged to decode bit 1 of 3 bits (i.e. K=3) using process described herein. The individual sections of the APB are labelled as follows:

| | |
|---|---|
| AV: | The absolute value circuit of FIG. 3; |
| MIRR: | A current mirror; |
| TANH: | The tanh circuit of FIG. 6, without the absolute value |
| | elements (i.e. just transistors M1 to M4); |
| TRANSR: | The transresistance circuit of FIG. 9, and; |
| SUBTR: | The subtraction circuit of FIG. 8. |

### Relation Between Numbers of Receiver Channels and Transistors

The total number of transistors needed, based on an embodiment of the invention, is in the order of

Trans=N_{S}(K(K−1)·18+K·13) (14)

where N_{S} is the required number of iterative stages and K is the number of bits to decode, based on the number of transmit antennas and the modulation scheme.

Thus, advantageously, the number of transistors used is proportional only to the square of the transmitted bits, rather than being exponential as is the case in the prior art.

Thus for this example, a quadrature phase shift key (QPSK) system with 10 transmit antennas (K=20), and decoding using 10 stages (N_{S}=10), would need 71,000 transistors.

This number of transistors may still be considered too many for some applications, however, so additional means may be considered to reduce the number of stages used.

### Variant Embodiments of the Analog MIMO Detector

Firstly, referring now to FIG. 15, a channel detector is shown arranged in operation to pass estimates of Lₖ, k=1, . . . , K to the analog equaliser. In an embodiment of the present invention, the inclusion of a channel detector is expected to significantly reduce the number of iterative stages required to 2 or 3 in the example above. Consequently, the number of transistors used would fall to 14,000 or 21,000 respectively.

The analog equaliser by itself starts with an initial log likelihood value of zero for each Lₖ and then iterates towards a solution. Consequently, the provision of an initial estimate for each Lₖ from a channel detector avoids the need to iterate from zero to an approximate value, so reducing the number of iteration stages needed. Optionally, as shown in FIG. 15 the output of the equaliser may then be passed back to the channel detector.

Referring now to FIG. 16, in an embodiment of the present invention a single analog processing block (APB) comprises a variable gain amplifier instead of the MOS level shifter of FIG. 10. In this arrangement, the outputs of the APB are fed back to its inputs in continuous time, while the amplification gain and temperature Tare also altered continuously as appropriate.

The use of the variable gain amplifier allows the APB to act as successive iterative stages, as T changes value (recall that the MOS level shifter in each chained APB required different transistors to accommodate different values of T).

Referring to FIGS. 17A and 17B, simulations suggest that such a feedback mechanism with a variable gain amplifier is stable. FIG. 17A shows a single APB stage iterating using feedback, while FIG. 17B shows a multiple APB stage feed forward version. Both are shown to converge similarly on the same randomly chosen input values. Advantageously, however, in the single-stage case the number of transistors used would only be approximately 7,000.

In an alternative embodiment, instead of a variable gain amplifier, the APB switches between different MOS level shifters according to a timing scheme, or according to the presence of a subsequent input voltage to the APB, so ratcheting through a set of fixed amplifications corresponding to each iteration of mₖ, and then outputting the result of the final level shifter.

It will be clear to a person skilled in the art that a combination of feed forward and feedback APBs may be used in assembling iterative stages. For example, a set of three feed forward stages may be used, wherein the output of the third stage feeds back to the input of the first, with variable gain amplifiers or switched level shifters set appropriately.

It will similarly be clear to a person skilled in the art that although the iterative stages described herein have been implemented using both bipolar (BJT) and CMOS devices, a fully CMOS implementation is possible by polarising the transistors in weak inversion where the voltage-current relationship is exponential as in the case of BJTs.

It will be clear to a person skilled in the art that currents for vector z may be copied in a similar fashion to R.

It will be clear to a person skilled in the art that the analog equaliser described herein may comprise a discrete entity, for example an ASIC, or plurality of entities, for example separate analog processing blocks. Similarly it will be clear to a person skilled in the art that the equaliser may form part of an analog MIMO detector, or equaliser for a reader of a magnetic storage medium. A more general device may be adapted to incorporate the analog equaliser, such as an entertainment device for games or streaming media, a laptop or PDA, or a hard drive. Alternatively, the equaliser may be a functionally separable component such as in a plug-in circuit board, or a peripheral such as a PCMIA card.

It will be understood that the analog equaliser disclosed herein provides one or more of the following advantages:
i. high speed detection for applications such as MIMO and disk reading;
ii. innate computation of soft values;
iii. iterative convergence toward an estimate of the MPEs;
iv. reduced complexity (a sub-exponential relationship between transistors and receiver channels), and;
v. a plurality of architectures to meet different component count restrictions.

1-23. (canceled)

24. An analog equalizer comprising:
an estimation means, the estimation means comprising at least a first analog processing block (APB) configured in operation to iteratively generate an estimate of marginal posterior expectations (MPEs) for received bit values.

25. An analog equalizer according to claim 24, wherein the estimation means further comprises scaling means to update the MPEs according to a mean field annealing factor.

26. An analog equalizer according to claim 24, wherein the estimation means further comprises coordinate descent minimization means for obtaining the MPE estimates.

27. An analog equalizer according to claim 24, comprising at least two APBs operably connected in succession, and configured in operation such that iteration is achieved by successive re-estimation of the MPEs by successive respective APBs.

28. An analog equalizer according to claim 27, wherein each successive APB is configured in operation to apply a lower mean field annealing factor than a preceding APB.

29. An analog equalizer according to claim 24, and comprising a processing chain of APBs, wherein outputs of a last in the processing chain of APBs are configured in use so as to feed back to inputs of a first APB in the chain, wherein a mean field annealing factor of each APB is lowered accordingly.

30. An analog equalizer according to claim 24, wherein outputs of a single APB are configured in use so as to feed back to its own inputs wherein a mean field annealing factor is lowered accordingly.

31. An analog equalizer according to claim 24, further comprising circuitry configured in operation to perform a calculation of general form
$${A}_{k} = \frac{a}{T} ( {B}_{k} - b {\sum }_{{k}^{′} = k}^{ } {C}_{{k}^{′}} , tanh ( \frac{{A}_{{k}^{′}}}{c} ) ) ,$$
given input values for A, B and C.

32. An analog equalizer according to claim 31, comprising circuitry configured to calculate
$${L}_{k} = \frac{2 a}{T} ( {z}_{k} - a {\sum }_{{k}^{′} = k} {\hat{R}}_{{k}^{′}} tanh ( \frac{{L}_{{k}^{′}}}{2} ) )$$
where L are log-likelihood ratios of the MPEs, T is an annealing factor, z is a signal model, and R is a channel cross-correlation matrix, for k=1, . . . , K bits.

33. An analog equalizer according to claim 24, wherein the first analog processing block (APB) includes:
a plurality of K sets of K-I Rk′.tanli calculation circuits, k=1, . . . , K, where K is the number of MPE estimates;
means for summing each of the K sets of K-I Rf.tanh calculation outputs;
means for subtracting each the sum from a respective filtered signal zi<5, k=1, . . . , K, and
means for scaling an output signal for each MPE estimate in inverse proportion to a mean field annealing factor T.

34. An analog equalizer according to claim 33, wherein each tanh calculation circuit comprises a transconductance amplifier, an absolute value generator and a Gilbert multiplier.

35. An analog equalizer according to claim 33, wherein each tanh calculation circuit comprises an absolute value circuit constructed with PMOS transistors forming two translinear loops, operably coupled to a transconductance amplifier.

36. An analog equalizer according to claim 33, and comprising a plurality of APBs wherein corresponding tanh calculation circuits within each APB share one absolute value circuit.

37. An analog equalizer according to claim 33, further comprising a transresistance circuit configured to substantially linearly convert an input current to an output voltage.

38. An ASIC comprising an analog equalizer in accordance with claim 24.

39. A multiple input, multiple output (MIMO) detector comprising an analog equalizer in accordance with claim 24.

40. A mobile communications device comprising an analog equalizer in accordance with claim 24.

41. A mobile communications device according to claim 40, wherein the mobile communications device is any one of:
i) a plug-in circuit board;
ii) a PCMIA card;
iii) a PDA;
iv) a laptop computer; or
v) an entertainment device.

42. A magnetic data storage device comprising an analog equalizer in accordance with claim 24.

43. A method of equalization comprising:
passing a plurality of log-likelihood marginal posterior expectations to an analog processing block (APB); and
generating in the APB a revised estimate of the log-likelihood marginal posterior expectations using coordinate descent optimization.

44. The method of claim 43, wherein subsequent re-estimations are performed by corresponding subsequent APBs.
